(19) United States
(12) Patent Application Publication
(10) Pub. No.: US 2012/0112243 A1
(43) Pub. Date: May 10, 2012

(54) Bipolar and FET Device Structure

(76) Inventors: Peter J. Zampardi, Newbury Park, CA (US); HsiangChih Sun, Thousand Oaks, CA (US)

(21) Appl. No.: 12/939,474

(22) Filed: Nov. 4, 2010

(51) Int. Cl. H01L 27/06; H01L 21/8249

(52) U.S. Cl. 257/192; 438/314; 257/E27.015; 257/E21.696

(57) ABSTRACT

A semiconductor structure includes a heterojunction bipolar transistor (HBT) including a collector layer located over a substrate, the collector layer including a semiconductor material, and a field effect transistor (FET) located over the substrate, the FET having a channel formed in the semiconductor material that forms the collector layer of the HBT.

### BACKGROUND

In some semiconductor material systems it is possible to combine different device technologies on a single semiconductor die to form hybrid structures. For example, in certain material systems, it is possible to integrate a heterojunction bipolar transistor (HBT) with a field effect transistors (FET) on a single substrate, to fabricate what is referred to as a BiFET. Devices, such as RF power amplifiers, can be fabricated using BiFET technology to have increased design flexibility. As a result, a BiFET power amplifier including an HBT and a FET can be advantageously designed to operate at a lower reference voltage than a bipolar transistor power amplifier. Of particular interest to device manufacturers are high power BiFET amplifiers, which can be formed by integrating a FET into a gallium arsenide (GaAs) HBT process. However, previous attempts to integrate a FET into a GaAs HBT process have resulted only in an n-type FET device.

Therefore, it would be desirable to have a BiFET device structure that includes a p-type FET device, and that may include complementary n-type and p-type FET devices.

### SUMMARY

Embodiments of a semiconductor structure include a heterojunction bipolar transistor (HBT) including a collector layer located over a substrate, the collector layer comprising a semiconductor material, and a field effect transistor (FET) located over the substrate, the FET comprising a channel formed in the semiconductor material that forms the collector layer of the HBT.

Other embodiments are also provided. Other systems, methods, features, and advantages of the invention will be or become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE FIGURES

The invention can be better understood with reference to the following figures. The components within the figures are not necessarily to scale, emphasis instead being placed upon clearly illustrating the principles of the invention. Moreover, in the figures, like reference numerals designate corresponding parts throughout the different views.

FIG. 1 is a schematic diagram illustrating a cross-sectional view of an exemplary structure including an exemplary BiFET.

FIG. 2 is a schematic diagram illustrating a cross-sectional view of an alternative embodiment of the structure of FIG. 1.

### DETAILED DESCRIPTION

Although described with particular reference to a device fabricated in the gallium arsenide (GaAs) material system, the structures described herein can be fabricated using other III-V semiconductor materials, such as indium phosphide (InP) and gallium nitride (GaN). Further, any of a variety of semiconductor growth, formation and processing technologies can be used to form the layers and fabricate the structure or structures described herein. For example, the semiconductor layers can be formed using molecular beam epitaxy (MBE), metal organic chemical vapor deposition (MOCVD), which is also sometimes referred to as organic metallic vapor phase epitaxy (OMVPE), or any other technique. Moreover, the thicknesses of the various semiconductor layers described below are approximate, and may range to thinner or thicker than that described. Similarly, the doping levels of the doped semiconductor layers described below are relative.

The present invention is directed to a semiconductor structure that includes a bipolar device, such as a heterojunction bipolar transistor (HBT), and a p-type field effect transistor (pFET) integrated on a common substrate, referred to generally as a BiFET, and formed in a GaAs material system. Embodiments also include a complementary BiFET (BiCFET) including a p-type FET (pFET) and an n-type FET (nFET) integrated with an HBT in a GaAs material system. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings. Certain details and features have been left out of the drawings, which will be apparent to a person of ordinary skill in the art. Although structure 100 illustrates an exemplary BiFET comprising an NPN HBT and a pFET, which are situated over a substrate in a semiconductor die, the present invention may also apply to a BiFET comprising a PNP HBT and an NFET; an NPN HBT and both an nFET and a pFET; and a PNP HBT and both an nFET and a pFET.

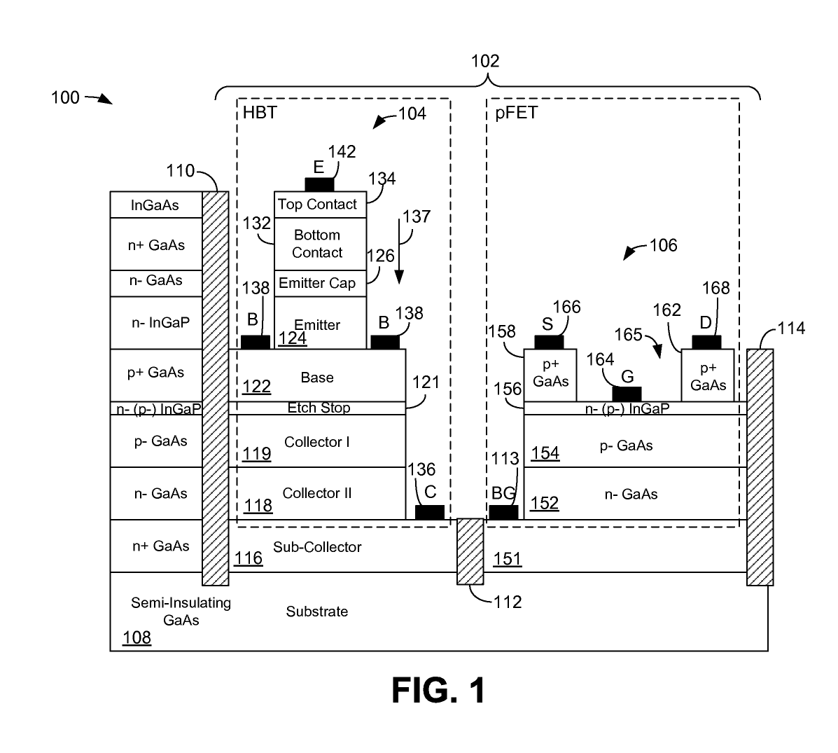

FIG. 1 is a schematic diagram illustrating a cross-sectional view of an exemplary structure including an exemplary BiFET in accordance with one embodiment of the present invention. Certain details and features have been left out of FIG. 1, which are apparent to a person of ordinary skill in the art. The structure 100 includes BiFET 102, isolation regions 110, 112, and 114, and substrate 108, which can be a semi-insulating GaAs substrate. The BiFET 102 includes an HBT 104, which is located over substrate 108 between isolation regions 110 and 112, and pFET 106, which is located over substrate 108 between isolation regions 112 and 114. Isolation regions 110, 112, and 114 provide electrical isolation from other devices on substrate 108 and can be formed in a manner known in the art.

The HBT 104 includes sub-collector layer 116, a first collector layer segment 118, a second collector layer segment 119, an optional etch-stop layer segment 121, a base layer segment 122, an emitter layer segment 124, an emitter cap layer segment 126, a bottom contact layer segment 132, a top contact layer segment 134, collector contact 136, base contacts 138, and emitter contact 142.

The pFET 106 includes a back gate contact 113, a lightly doped N type GaAs segment 152, a lightly doped P type GaAs segment 154, an optional etch stop layer segment 156, typically comprising lightly doped N type or P type InGaP, source contact layer 158 and drain contact layer 162, typically comprising heavily doped P type GaAs, gate contact 164, source contact 166, and drain contact 168. Alternatively, the optional etch stop layer segment 156 can be undoped. In the present embodiment, the HBT 104 can be an NPN HBT integrated in a complementary arrangement with the pFET 106. In another embodiment, the HBT 104 can be a PNP HBT integrated with an nFET, or can be a PNP HBT or an NPN HBT integrated with the pFET 106 and with an nFET. In the present embodiment, the pFET 106 can be a depletion mode FET or an enhancement mode FET.

The sub-collector layer 116 is situated on substrate 108 and can comprise heavily doped N type GaAs. The sub-collector layer 116 can be formed by using a metal organic chemical vapor deposition (MOCVD) process or other processes. The first collector layer segment 118 and the collector contact 136 are located on the sub-collector layer 116. The first collector layer segment 118 can comprise lightly doped N type GaAs. The second collector layer segment 119 can comprise lightly doped P type GaAs. The first collector layer segment 118 and the second collector layer segment 119 can be formed by using a MOCVD process or other processes. The collector contact 136 can comprise an appropriate metal or combination of metals, which can be deposited and patterned over the sub-collector layer 116.

The optional etch stop layer segment 121 can be located on the second collector layer segment 119 and can comprise lightly doped N type or P type InGaP. Alternatively, the optional etch stop layer segment 121 can be undoped. The etch stop layer segment 121 can be formed by using a MOCVD process or other processes.

The base layer segment 122 is located on the etch stop layer segment 121 and can comprise heavily doped P type GaAs. The base layer segment 122 can be formed by using a MOCVD process or other processes.

The emitter layer segment 124 and base contacts 138 are located on base layer segment 122. The emitter layer segment 124 can comprise lightly doped N type indium gallium phosphide (InGaP) and can be formed on the base layer segment 122 by using a MOCVD process or other processes. The base contacts 138 can comprise an appropriate metal or combination of metals, which can be deposited and patterned over base layer segment 122. The emitter cap layer segment 126 is located on the emitter layer segment 124 and can comprise lightly doped N type GaAs. The emitter cap layer segment 126 can be formed by using a MOCVD process or other processes.

The bottom contact layer segment 132 is located on the emitter cap layer segment 126 and can comprise heavily doped N type GaAs. The bottom contact layer segment 132 can be formed by using an MOCVD process or other processes.

The top contact layer segment 134 is situated on the bottom contact layer segment 132 and can comprise heavily doped N type indium gallium arsenide (InGaAs). The top contact layer segment 134 can be formed by using a MOCVD process or other processes. The emitter contact 142 is located on the top contact layer segment 134 and can comprise an appropriate metal or combination of metals, which can be deposited and patterned over top contact layer segment 134.

During operation of the HBT 104, current flows from the emitter contact 142, through the top contact layer segment 134, bottom contact layer segment 132, emitter cap layer segment 126, emitter layer segment 124, and into the base layer segment 122 and is indicated by arrow 137.

To form the pFET 106 in the collector of the HBT 104, a lightly doped P type GaAs layer segment 154 is located over a lightly doped N type GaAs layer segment 152, which is located over a heavily doped N type GaAs layer segment 151. A back gate contact 113 is formed on the heavily doped N type GaAs layer segment 151 to create a back gate for the pFET 106. The back gate contact 113 can comprise an appropriate metal or combination of metals, which can be deposited and patterned over the heavily doped N type GaAs layer segment 151.

The lightly doped N type GaAs layer segment 152 is substantially similar in composition and formation to the first collector layer segment 118 discussed above. The lightly doped P type GaAs layer segment 154 is substantially similar in composition and formation to the second collector layer segment 119 discussed above.

The lightly doped P type GaAs layer segment 154 forms the channel of the pFET 106. The etch stop layer segment 156 is situated on the lightly doped P type GaAs layer segment 154 and can comprise lightly doped N type or P type InGaP. Alternatively, the etch stop layer segment 156 can be undoped. The etch stop layer segment 156 can be formed on the lightly doped P type GaAs layer segment 154 by using a MOCVD process or other appropriate processes. If implemented, the etch stop layer segment 156 can have a thickness between approximately 10 nanometers (nm) and approximately 15 nm. In one embodiment, the pFET 106 can be an enhancement mode FET and the etch stop layer segment 156 can have a thickness less than 10 nm.

The source contact layer 158 and the drain contact layer 162 are located on the etch stop layer segment 156 and can comprise heavily doped P type GaAs to form source and drain regions, respectively. The source and drain contact layers 158 and 162 can be formed by using a MOCVD process or other processes. A source contact 166 and drain contact 168 are located on the etch stop layer segment 156. Source contact 166 and drain contact 168 can comprise platinum gold (“PtAu”) or other appropriate metals and can be formed in a manner known in the art. A gate contact 164 is located on the etch stop layer segment 156 in gap 165, which is formed between source and drain contact layers 158 and 162, and can comprise an appropriate metal or combination of metals. The gap 165 can be formed by utilizing an appropriate etch chemistry to selectively etch through a layer of InGaAs and a layer of GaAs and stop on etch stop layer segment 156. After the gap 165 has been formed, gate contact 164 can be formed on etch stop layer segment 156 in a manner known in the art. In one embodiment, the FET 106 can be an enhancement mode FET and gate contact 164 can be formed directly on the lightly doped P type GaAs layer segment 154. In that embodiment, an appropriate etch chemistry can be utilized to selectively etch through etch stop layer segment 156 and stop on lightly doped P type GaAs layer segment 154.

Thus, by forming the pFET 106 in the layers that comprise the collector of the HBT 104, a pFET can be integrated with an NPN HBT, yielding a complementary BiFET.

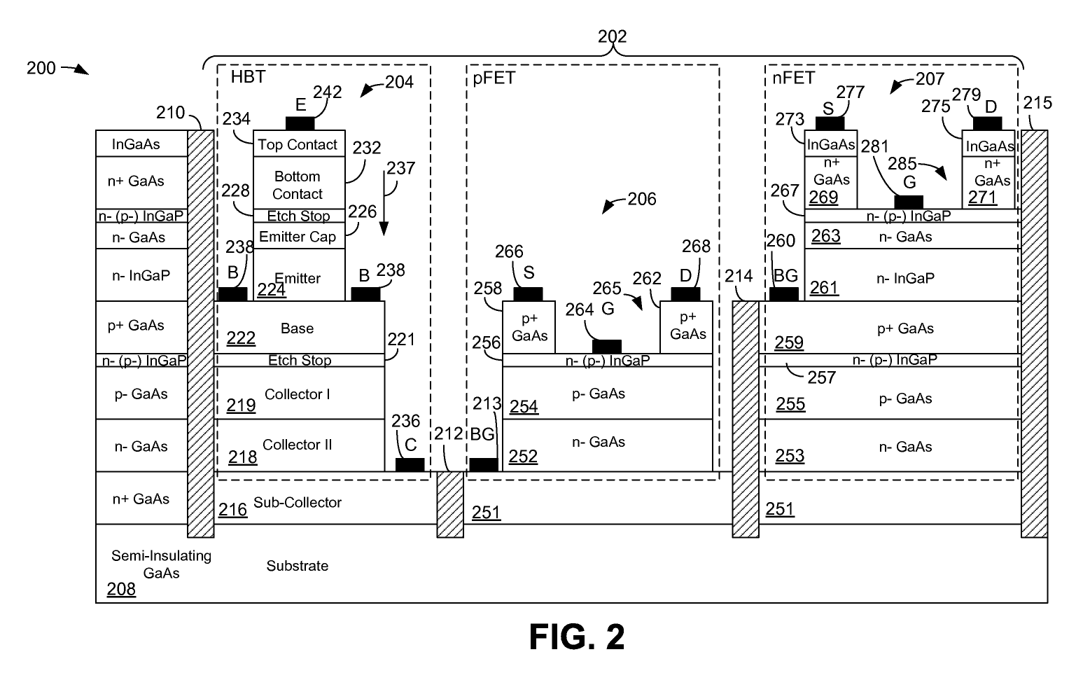

FIG. 2 is a schematic diagram illustrating a cross-sectional view of an alternative embodiment of the structure of FIG. 1. The structure 200 shown in FIG. 2 includes a BiCFET structure that includes an HBT 204, a pFET 206 and an nFET 207.

Elements and structures in FIG. 2 that are similar to corresponding elements and structures in FIG. 1 will not be described again in detail, but instead, will be referred to using the nomeclature 2XX, where “XX” refers to a similar element in FIG. 1.

The BiCFET 202 includes an HBT 204 located between isolation region 210 and isolation region 212, a pFET 206 located between isolation region 212 and 214, and includes an nFET 207 located between isolation region 214 and isolation region 215.

The HBT 204 includes sub-collector layer 216, a first collector layer segment 218, a second collector layer segment 219, an optional etch-stop layer segment 221, a base layer segment 222, an emitter layer segment 224, an emitter cap layer segment 226, a second optional etch stop layer 228, a bottom contact layer segment 232, a top contact layer segment 234, collector contact 236, base contacts 238, and emitter contact 242.

The pFET 206 comprises a lightly doped P type GaAs layer segment 254 located over a lightly doped N type GaAs layer segment 252, which is located over a heavily doped N type GaAs layer segment 251. A back gate contact 213 is formed on the heavily doped N type GaAs layer segment 251 to create a back gate for the pFET 206. The back gate contact 213 can comprise an appropriate metal or combination of metals, which can be deposited and patterned over the heavily doped N type GaAs layer segment 251.

The lightly doped P type GaAs layer segment 254 forms the channel of the pFET 206. The etch stop layer segment 256 is situated on the lightly doped P type GaAs layer segment 254 and can comprise lightly doped N type or P type InGaP. Alternatively, the optional etch stop layer segment 256 can be undoped. The etch stop layer segment 256 can be formed on the lightly doped P type GaAs layer segment 254 by using a MOCVD process or other appropriate processes. If implemented, the etch stop layer segment 256 can have a thickness between approximately 10 nanometers (nm) and approximately 15 nm. The source contact layer 258 and the drain contact layer 262 are located on the etch stop layer segment 256 and can comprise heavily doped P type GaAs to form source and drain regions, respectively. A source contact 266 and drain contact 268 are located on the etch stop layer segment 256. A gate contact 264 is located on the etch stop layer segment 256 in gap 285, which is formed between source and drain regions 258 and 262, and can comprise an appropriate metal or combination of metals.

To form the nFET 207 in the layers that comprise the emitter of the HBT 104, a lightly doped P type GaAs layer segment 255 is located over a lightly doped N type GaAs layer segment 253, which is located over the heavily doped N type GaAs layer segment 251. The lightly doped N type GaAs layer segment 253 is substantially similar in composition and formation to the first collector layer segment 118 discussed above. The lightly doped P type GaAs layer segment 255 is substantially similar in composition and formation to the second collector layer segment 119 discussed above.

An etch stop layer segment 257 is located on the lightly doped P type GaAs layer segment 255 and is similar to the etch stop layer segment 256.

A heavily doped P type GaAs layer segment 259 is located on the etch stop layer segment 257 and is substantially similar in composition and formation to base layer segment 122 discussed above. A back gate contact 260 is formed on the heavily doped P type GaAs layer segment 259 to create a back gate for the nFET 207. The back gate contact 260 can comprise an appropriate metal or combination of metals, which can be deposited and patterned over the heavily doped P type GaAs layer segment 259. A lightly doped N type InGaP segment 261 is located on the heavily doped P type GaAs segment 259 and is substantially similar in composition and formation to the emitter layer segment 124 discussed above.

A lightly doped N type GaAs layer segment 263 is located on the lightly doped N type InGaP layer segment 261 and is substantially similar in composition and formation to the emitter cap layer segment 126 discussed above. The lightly doped N type GaAs layer segment 263 forms a channel for the nFET 207. The second optional etch stop layer segment 267 is located on the lightly doped N type GaAs layer segment 263 and can comprise lightly doped N type or P type InGaP. Alternatively, the second optional etch stop layer segment 267 can be undoped. The second optional etch stop layer segment 267 can be formed on the lightly doped N type GaAs layer segment 263 by using a MOCVD process or other appropriate processes. In an embodiment, the second optional etch stop layer segment 267 can have a thickness between approximately 10 nm and approximately 15 nm In an embodiment, the nFET 207 can be an enhancement mode FET and the etch stop layer segment 267 can have a thickness less than 10 nm.

A source region 269 and drain region 271 are located on the second optional etch stop layer segment 267 and can comprise heavily doped N type GaAs. The source region 269 and the drain region 271 can be formed by using a MOCVD process or other processes. Contact layer segments 273 and 275 are located on source and drain regions 269 and 271, respectively, and can comprise heavily doped N type InGaAs. Contact layer segments 273 and 275 can be formed by using a MOCVD process or other processes.

A source contact 277 and a drain contact 279 are located on top contact layer segments 271 and 273, respectively. A gate contact 281 is located on the second optional etch stop layer segment 267 in gap 285. Gap 285 can be formed by utilizing an appropriate etch chemistry to selectively etch through a layer of InGaAs and a layer of GaAs and stop on second optional etch stop layer segment 267. After gap 285 has been formed, gate contact 281 can be formed on the second optional etch stop layer segment 267 in a manner known in the art. In an embodiment, the nFET 207 can be an enhancement mode FET and gate contact 281 can be formed directly on lightly doped N type GaAs layer segment 263. In that embodiment, an appropriate etch chemistry can be utilized to selectively etch through the second optional etch stop layer segment 267 and stop on lightly doped N type GaAs layer segment 263.

Accordingly, a BiCFET can be fabricated that includes complementary pFET 206 and nFET 207, formed on a GaAs substrate along with either an NPN or a PNP HBT.

While various embodiments of the invention have been described, it will be apparent to those of ordinary skill in the art that many more embodiments and implementations are possible that are within the scope of the invention. For example, the invention is not limited to the gallium arsenide material system.

What is claimed is:

1. A semiconductor structure, comprising:
a heterojunction bipolar transistor (HBT) including a collector layer located over a substrate, the collector layer comprising a semiconductor material; and
a field effect transistor (FET) located over the substrate, the FET comprising a channel formed in the semiconductor material that forms the collector layer of the HBT.

2. The semiconductor structure of claim 1, in which the semiconductor material that forms the collector layer of the HBT and the channel of the FET comprises p-type gallium arsenide.

3. The semiconductor structure of claim 1, further comprising an etch stop layer segment located over the collector layer of the HBT and the channel of the FET.

4. The semiconductor structure of claim 3, wherein the etch stop layer comprises indium gallium arsenide.

5. The semiconductor structure of claim 4, wherein the etch stop layer has a thickness range between 10 nanometers (nm) and 15 nm

6. A semiconductor structure, comprising:
a heterojunction bipolar transistor (HBT) including a collector layer located over a substrate and an emitter layer located over the substrate, the collector layer comprising a first semiconductor material of a first conductivity type (P), the emitter layer comprising a second semiconductor material of a second conductivity type (N);
a first field effect transistor (FET) located over the substrate, the first FET comprising a channel formed in the first semiconductor material that forms the collector layer of the HBT; and
a second field effect transistor (FET) located over the substrate, the second FET comprising a channel formed in the second semiconductor material that forms the emitter layer of the HBT.

7. The semiconductor structure of claim 6, in which:
the first semiconductor material that forms the collector layer of the HBT and the channel of the first FET comprises p-type gallium arsenide; and
the second semiconductor material that forms the emitter layer of the HBT and the channel of the second FET comprises n-type gallium arsenide.

8. The semiconductor structure of claim 6, further comprising:
a first etch stop layer segment located over the collector layer of the HBT and the channel of the first FET; and
a second etch stop layer segment located over the emitter layer of the HBT and the channel of the second FET.

9. The semiconductor structure of claim 8, wherein the first etch stop layer segment and the second etch stop layer segment comprise indium gallium arsenide.

10. The semiconductor structure of claim 9, wherein the first etch stop layer segment and the second etch stop layer segment have a thickness range between 10 nanometers (nm) and 15 nm

11. A method, comprising:
forming a heterojunction bipolar transistor (HBT) including a collector layer located over a substrate and an emitter layer located over the substrate, the collector layer comprising a first semiconductor material of a first conductivity type (P), the emitter layer comprising a second semiconductor material of a second conductivity type (N);
forming a first field effect transistor (FET) over the substrate, the first FET comprising a channel formed in the first semiconductor material that forms the collector layer of the HBT; and
forming a second field effect transistor (FET) over the substrate, the second FET comprising a channel formed in the second semiconductor material that forms the emitter layer of the HBT.

12. The method of claim 11, further comprising:
forming the first semiconductor material that forms the collector layer of the HBT and the channel of the first FET using p-type gallium arsenide; and
forming the second semiconductor material that forms the emitter layer of the HBT and the channel of the second FET using n-type gallium arsenide.

13. The method of claim 11, further comprising:
forming a first etch stop layer segment over the collector layer of the HBT and the channel of the first FET; and
forming a second etch stop layer segment over the emitter layer of the HBT and the channel of the second FET.

14. The method of claim 13, further comprising forming the first etch stop layer segment and the second etch stop layer segment using indium gallium arsenide.

15. The method of claim 14, further comprising forming the first etch stop layer segment and the second etch stop layer segment to a thickness range between 10 nanometers (nm) and 15 nm.
